(19) United States
(12) Patent Application Publication
(10) Pub. No.: US 2023/0117613 A1
(43) Pub. Date: Apr. 20, 2023

(54) Carbon Graphene Compound Additive to Eliminate ESD and EMI, and Also Manipulate Dielectric Constant

(71) Applicant: Ving Dee Pu, Irwindale, CA (US)

(72) Inventor: Ving Dee Pu, Irwindale, CA (US)

(21) Appl. No.: 17/504,095

(22) Filed: Oct. 18, 2021

(51) Int. Cl. H05K 9/00

(52) U.S. Cl. CPC H05K 9/0083; H05K 9/0079

(57) ABSTRACT

This invention provides a superior additive allowing a more precise control of the dielectric constant of a non-conductive polymer such as thermoplastics, unsaturated polyester, polyurethane or epoxy by the addition of planar graphite made into nanoparticles, or more particularly graphene. Carbon black, saline or acrylic can also be used together with the graphene. Results achieved through the use of this additive include shielding of EMI, Elimination of ESD, increasing of conductivity, or the fine tuning of the dielectric constant within a needed range.

### CROSS-REFERENCE TO RELATED APPLICATIONS

There are no related applications.

### STATEMENT REGARDING FEDERALLY SPONSORED RESEARCH OR DEVELOPMENT

This invention was not made using federally sponsored research or development. The inventor retains all rights.

### THE NAMES OF THE PARTIES TO A JOINT RESEARCH AGREEMENT

Not applicable.

### BACKGROUND OF THE INVENTION

This invention falls within the field of additives to polymer material to control its dielectric constant and preparing conductive additives for non-conductive material or to improve already conductive polymers. Placing a conductive pigment such as carbon black and graphene into an unsaturated polyester resin is already known to the art. (See e.g. Buhl et al. EP 0949633A1).

### BRIEF SUMMARY OF THE INVENTION

This invention provides a superior additive allowing a more precise control of the dielectric constant of a non-conductive polymer such as thermoplastics, unsaturated polyester, polyurethane or epoxy by the addition of planar graphite made into nanoparticles, or more particularly graphene. Saline in the form of an acrylate polymer is an additive that can create bonding with the polymer on one side of the molecule while the other side of the molecule can bond with a filler such as Aluminum Tri-Hydrate, Calcium carbonate, Aluminum Nitride etc. Carbon black can also be used together with the graphene and resin. Results achieved through the use of this additive include shielding of EMI, Elimination of ESD, increasing of conductivity, or the fine tuning of the dielectric constant within a needed range.

### BRIEF DESCRIPTION OF THE SEVERAL VIEWS OF THE DRAWING

FIG. 1 is a perspective view of a block of resin containing graphene, carbon black, saline, and filler.

### DETAILED DESCRIPTION OF THE INVENTION

This invention provides a superior additive allowing a more precise control of the dielectric constant of a non-conductive polymer such as thermoplastics, unsaturated polyester, polyurethane or epoxy by the addition of planar graphite made into nanoparticles, or more particularly graphene. Carbon black, saline or acrylic can also be used together with the graphene and resin. Saline in the form of an acrylate polymer is an additive that can create bonding with the polymer on one side of the molecule while the other side of the molecule can bond with a filler such as Aluminum Tri-Hydrate, Calcium carbonate, Aluminum Nitride etc. Acrylate polymers are polymers of acrylate monomers which are in turn based on the structure of acrylic acid consisting of a vinyl group and a carboxylic acid ester terminus or a nitrile. A non-exclusive list of acrylate monomers that can be used to create acrylate polymers or co-polymers includes Methyl Methacrylate, Methacrylate, Methyl Acrylate, 2-Chloroethyl Vinyl Ether, 2-Ethylhexyl Acrylate, Hydroxyethyl Methacrylate, Butyl Acrylate, Butyl Methacrylate, and Trimethylolpropane Triacrylate. The additive can attach at one end to resin and at the other end attach to graphene or carbon black. Results achieved through the use of this additive include shielding of EMI, elimination of ESD, increasing of conductivity, or the fine tuning of the dielectric constant within a needed range.

The following is a non-exclusive list of substrates or polymers with which the invention can be produced: fiberglass, UPR resin, epoxy resin, polypropylene, polyurethane, PU/butadiene rubber, Nylon, PET. A different type of the saline additive would be used for each of these substrates to optimize the covalent bond formed with the polymer or acrylate type in order to form a three dimensional network that encapsulates all the graphene and improve conductivity. Such covalent bonds are close to the ionic bonds that are formed when a metal filler is used and they lead to the formation of a stable three dimensional structure comprised of the resin, graphene, carbon black, and polymer components that would not ordinarily bond in the absence of the saline.

Alternatively, the specific saline additive can be manipulated in order to improve the bonding. Different applications can be made in either thermoset or thermoplastic substrates and the additive can even sometimes strengthen the substrate material.

The mixture of graphene nanoparticles and resin can be used as a conductive additive for non-conductive materials such as fiber glass. These coated materials can in turn be assembled into laminar structures in various applications, with conductive and non-conductive layers both being present. The specific nature of the application can be changed by changing the dielectric constant of the laminate. Military and other applications are even possible by shielding of EMI.

Anti-static applications such as anti-static coatings for storage tanks are possible because of the invention's elimination of ESD. Coatings produced with this invention can also give increased resistance to acidic conditions, etc.

In a preferred embodiment, the carbon black is ground to a size of 1 to 2 microns and then combined with the graphene. Damaged particles of graphene can lack electrons at certain places on the perimeter of the molecule and the carbon black can associate with the graphene in the three dimensional structure in order to supply or share electrons with the damaged graphene. Resistance can be reduced from 10²³ ohms to 10³ ohms. Less expensive graphene, which is mined rather than produced by the methane deposition process, often has such damage around the edges. The use of carbon black to supply missing electrons allows more effective use of such mined graphene.

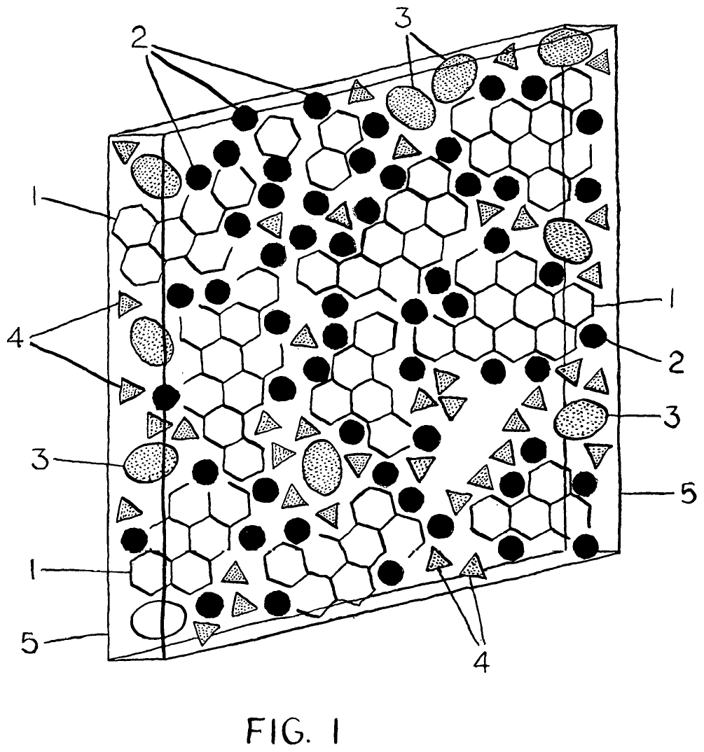

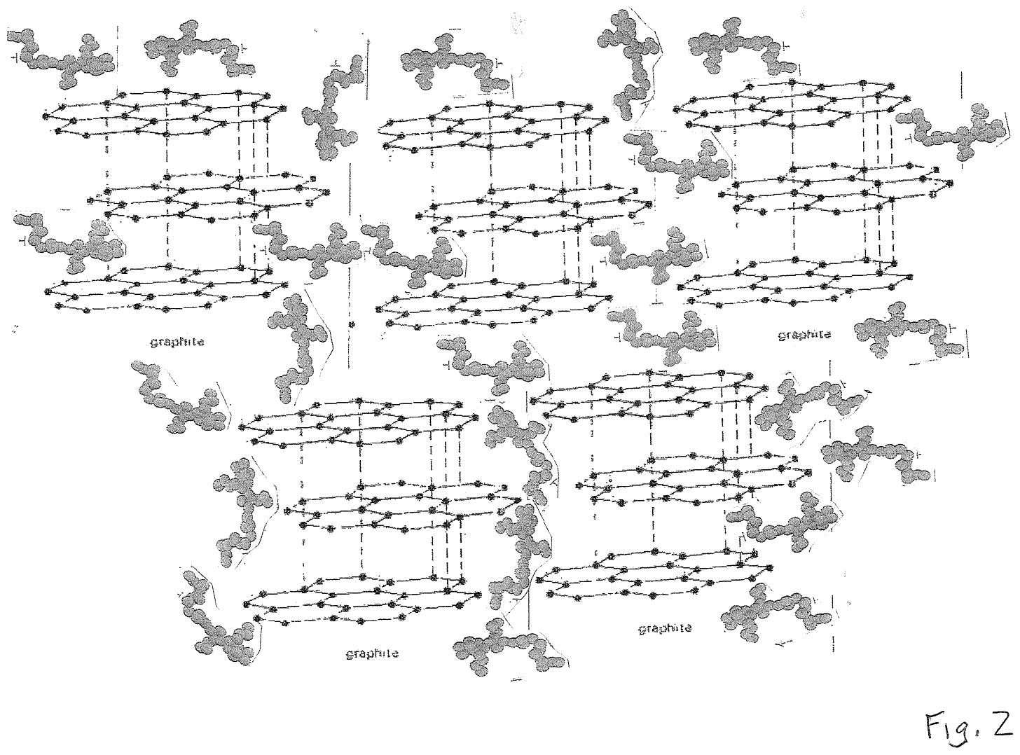

Turning now to. FIG. 1, graphene (1) can be seen in a three dimensional structure with carbon black (2), saline (3), and filler (4). The filler can be Aluminum Tri-Hydrate, Calcium Carbonate, Aluminum Nitride etc. A non-conductive polymer (5) surrounds and contains the entire structure.

I claim:

1. In combination; a non-conductive polymer, a filler, and a saline;
said filler consisting of at least one material selected from the group consisting of aluminum tri-hydrate, calcium carbonate, aluminum nitride, graphene, and carbon black;
said saline consisting of an acrylate polymer having a wet end and a dry end, wherein said wet end can bond with said filler and said dry end can bond with said non-conductive polymer.

2. The combination of claim 1 wherein said non-conductive polymer consists of at least one material selected from the group consisting of unsaturated polyester resin, epoxy resin, polyurethane, butadiene rubber, polypropylene, nylon, and polyethylene terephthalate.

3. The combination of claim 1 wherein said filler comprises planar graphene.

4. The combination of claim 1 wherein said non-conductive polymer consists of at least one material selected from the group consisting of unsaturated polyester resin, epoxy resin, polyurethane, butadiene rubber, polypropylene, nylon, and polyethylene terephthalate; and said filler comprises planar graphene.

5. The combination of claim 1 further comprising fiberglass.

6. The combination of claim 1 wherein said filler comprises carbon black ground to a size between 1 and 2 microns.

7. A laminate structure comprising at least one layer of fiberglass and at least one layer of a material comprising a non-conductive polymer, a filler, and a saline;
said filler consisting of at least one material selected from the group consisting of aluminum tri-hydrate, calcium carbonate, aluminum nitride, graphene, and carbon black;
said saline consisting of an acrylate polymer having a wet end and a dry end, wherein said wet end can bond with said filler and said dry end can bond with said non-conductive polymer.

8. The laminate structure of claim 7 wherein said non-conductive polymer consists of at least one material selected from the group consisting of unsaturated polyester resin, epoxy resin, polyurethane, butadiene rubber, polypropylene nylon, and polyethylene terephthalate.

9. The laminate structure of claim 7 wherein said filler comprises planar graphene.

10. The laminate structure of claim 7 wherein said non-conductive polymer consists of at least one material selected from the group consisting of unsaturated polyester resin, epoxy resin, polyurethane, butadiene rubber, polypropylene nylon, and polyethylene terephthalate; and said filler comprises planar graphene.

11. The laminate structure of claim 10 wherein said filler further comprises carbon black ground to a size between 1 and 2 microns.

12. The laminate structure of claim 6 wherein said filler comprises carbon black ground to a size between 1 and 2 microns.

13. An improved three dimensional combination of graphene and a non-conductive polymer wherein the improvement comprises carbon black particles associated with the perimeter of said graphene and supplying electrons to said graphene.

14. The invention of claim 13 further comprising Al₂O₅ 3H₂O added to said three-dimensional combination.

15. The invention of claim 13 further comprising AlN added to said three-dimensional combination.

16. The invention of claim 15 further comprising Al₂O₅ 3H₂O added to said three-dimensional combination.
